(19) United States
(12) Patent Application Publication
(10) Pub. No.: US 2011/0227228 A1
(43) Pub. Date: Sep. 22, 2011

(54) FILLING COMPOSITION, SEMICONDUCTOR DEVICE INCLUDING THE SAME, AND METHOD OF FABRICATING THE SEMICONDUCTOR DEVICE

(75) Inventors: Yong Sung EOM, Daejeon (KR); Jong Tae Moon, Chungcheongnam-do (KR); Kwang-Seong Choi, Daejeon (KR); Hyun-cheol Bae, Daejeon (KR); Jong Jin Lee, Daejeon (KR)

(73) Assignee: ELECTRONICS AND TELECOMMUNICATIONS RESEARCH INSTITUTE, Daejeon (KR)

(21) Appl. No.: 12/886,927

(22) Filed: Sep. 21, 2010

(30) Foreign Application Priority Data
Mar. 19, 2010 (KR) 10-2010-0027848

(51) Int. Cl. H01L 23/488; H01B 1/22; H01L 21/50

(52) U.S. Cl. 257/772; 252/512; 438/107; 257/E23.023; 257/E21.499

(57) ABSTRACT

Provided is a filling composition. The filling composition includes: a first particle including Cu and/or Ag; a second particle electrically connecting the first particles; and a resin containing a high molecular compound, a hardener, and a reducer, in which the first and second particles are dispersed, wherein the hardener includes amine and/or anhydride, and the reducer includes carboxyl.

### CROSS-REFERENCE TO RELATED APPLICATION

This U.S. non-provisional patent application claims priority under 35 U.S.C. §119 of Korean Patent Application No. 10-2010-0027848, filed on Mar. 29, 2010, the entire contents of which are hereby incorporated by reference.

### BACKGROUND OF THE INVENTION

The present invention disclosed herein relates to a filling composition, a semiconductor device including the same, and a method of fabricating the semiconductor device, and more particularly, to a filling composition electrically connecting substrates by being disposed therebetween, a semiconductor device including the same, and a method of fabricating the semiconductor device.

Generally, conductive patterns that electrically connect a plurality of substrates by being disposed between the substrates are formed by using a composition which typically includes silver particles and resin in the process of manufacturing semiconductor devices. The composition including only silver particles and resin has a resistance that is increased by an oxide in the resin or other external conditions. Accordingly, if conductive patterns made from the composition are formed to electrically connect substrates by being disposed therebetween, the electric resistance of the conductive patterns becomes high, such that defects in the electrical connection may occur.

### SUMMARY OF THE INVENTION

The present invention provides a filling composition having a low electrical resistance.

The present invention also provides a semiconductor device including the filling composition.

The present invention also provides a method of fabricating the semiconductor device.

Embodiments of the present invention provide filling compositions including: a first particle including Cu and/or Ag; a second particle electrically connecting the first particles; and a resin containing a high molecular compound, a hardener, and a reducer, in which the first and second particles are dispersed, wherein the hardener includes amine and/or anhydride, and the reducer includes carboxyl.

In some embodiments, the first particle may occupy about 5 volume % to about 40 volume % of the composition; and the second particle occupy about 5 volume % to about 40 volume % of the composition.

In other embodiments, the first and second particles may occupy about 30 volume % to about 50 volume % of the composition.

In still other embodiments, the second particle may be at least one selected from the group consisting of Sn, Bi, In, Ag, Pb, and Cu.

In even other embodiments, the second particle may be at least one selected from the group consisting of 60Sn/40Bi, 52In/48Sn, 97In/3Ag, 57Bi/42Sn/1Ag, 58Bi/42Sn, 52Bi/32Pb/16Sn, and 96.5Sn/3Ag/0.5Cu.

In yet other embodiments, the high molecular compound may include at least one monomer selected from the group consisting of A (diglycidyl ether of bisphenol A, DBEBA), (tertraglycidyl4,4′-diaminodiphenyl methane, TGDDM), tridiaminodiphenyl methane, triDDM), isocyanate, and bismaleimide.

In further embodiments, the hardener may have an equivalent of an about 0.4 to about 1.2 of the high molecular compound.

In still further embodiments, the hardener may be at least one selected from the group consisting of (m-phenylenediamine, MPDA), (diaminodiphenyl methane, DDM), (diaminodiphenyl sulphone, DDS), (methylnadic anhydride, MNA), (dodecenyl succinic anhydride, DDSA), (maleic anhydride, MA), (succinic anhydride, SA), (methyl tetrahydrophthalic anhydride, MTHPA), (hexahydrophthalic Anhydride, HHPA), (tetrahydrophthalic anhydride, THPA), and (pyromellitic dianhydride, PMDA).

In even further embodiments, the reducer may be added in an amount of less than about 10 per hundred resin (phr) of the weight of the resin.

In yet further embodiments, the reducer may be at least one selected from the group consisting of glutaric acid, malic acid, azelaic acid, abietic acid, adipic acid, ascorbic acid, acrylic acid, and citric acid.

In yet further embodiments, the diameter of the first particle is between about 1 μm and 30 μm and the diameter of the second particle is between about 5 nm and 100 μm.

In yet further embodiments, the filling compositions may further include a catalyst and a deforming agent.

In yet further embodiments, the catalyst may be added in an amount of less than 30 per hundred resin (phr) of the weight of the resin.

In yet further embodiments, the catalyst may be at least one selected from the group consisting of (benzyl dimethyl amine, BDMA), boron trifluoride monoethylamine comples, BF3-MEA), (dimethylamino methyl phenol, DMP), and (dimethyl benzol amine, DMBA).

In yet further embodiments, the deforming agent may be at least one selected from the group consisting of acrlylate oligomer, polyglycols, glycerides, polypropylene glycol, demethylsilicon, simethicone, tributyl phosphate, and polydimethylsiloxane.

In other embodiments of the present invention, semiconductor devices include: a first substrate formed with a first conductive pattern; a second substrate formed with a second conductive pattern that is disposed to face the first conductive pattern; and a connection pattern electrically connecting the first and second conductive patterns, wherein the connection pattern includes a filling composition formed of a resin that contains a particle including Cu or Ag, solder powder, a high molecular compound, a hardener, and a reducer; the hardener includes amine and/or anhydride; and the reducer includes carboxyl.

In some embodiments, the solder powder may be at least one selected from the group consisting of Sn, Bi, In, Ag, Pb, and Cu and electrically connects the Cu particles.

In other embodiments, the Cu particle may occupy about 5 volume % to about 40 volume % of the filling composition; and the solder power may occupy about 5 volume % to about 40 volume % of the filling composition.

In still other embodiments of the present invention, methods of fabricating a semiconductor device include: preparing a first substrate formed with a conductive pattern; forming a preliminary connection pattern on the first substrate; preparing a second substrate formed with a second conductive pattern; positioning the second substrate to allow the second conductive pattern to contact the preliminary connection pattern; and forming a connection pattern that electrically connects the first and second conductive patterns by applying heat to the preliminary connection pattern, wherein the preliminary connection pattern includes a filling composition formed of a resin that contains a particle including Cu or Ag, solder powder, a high molecular compound, a hardener, and a reducer; the hardener includes amine and/or anhydride; and the reducer includes carboxyl.

In some embodiments, the forming of a connection pattern may include: removing an oxide in the preliminary connection pattern through the reducer by applying heat to the preliminary connection pattern; and electrically connecting the Cu particles by expansion of a ball of the solder powder.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view illustrating a filling composition according to an embodiment of the present invention;

FIGS. 2A through 2E are sectional views illustrating a method of fabricating a semiconductor device according to an embodiment of the present invention; and

FIG. 3 is a graph illustrating the contact resistance values of the filling compositions of Examples 1 to 3 and Comparative Example.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

Additionally, the embodiment in the detailed description will be described with sectional views as ideal exemplary views of the present invention. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. Areas exemplified in the drawings have general properties, and are used to illustrate a specific shape of a semiconductor package region. Thus, this should not be construed as limited to the scope of the present invention. For example, an etched region illustrated as a rectangle may have rounded or curved features. Also, though terms like a first and a second are used to describe various members, components, regions, layers, and/or portions in various embodiments of the present invention, the members, components, regions, layers, and/or portions are not limited to these terms.

In the following description, the technical terms are used only for explaining specific embodiments while not limiting the present invention. The terms of a singular form may include plural forms unless referred to the contrary.

Hereinafter, exemplary embodiments of the present invention will be described in conjunction with the accompanying drawings.

(Filling Composition)

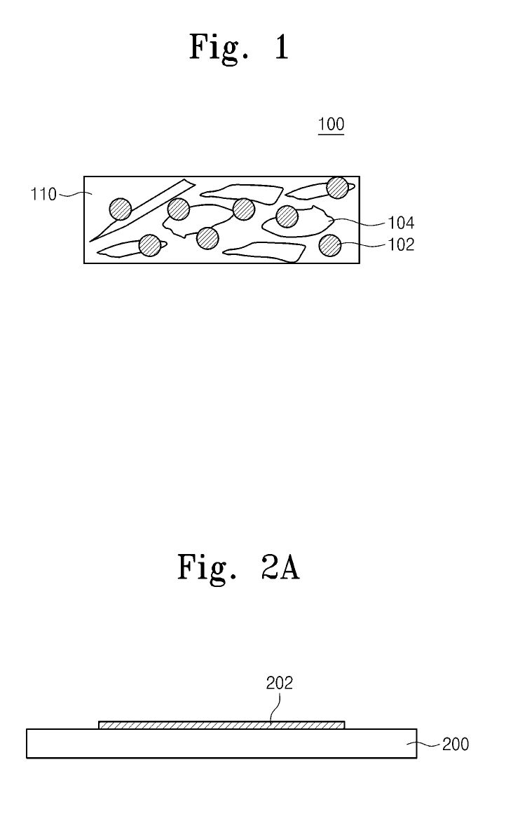

FIG. 1 is a view illustrating a filling composition according to an embodiment of the present invention.

Referring to FIG. 1, the filling composition 100 may include a first particle 104, a second particle 102, and a resin 110 including a hardener and a reducer.

The first particle 104 may include copper and/or silver. If the particle 104 includes both copper and silver, it is not in a compound form but in a mixture form. The first particle 104 may have a plate shape structure. The size of the first particle 104 may range between about 1 μm and about 30 μm. For example, if the first particle is in plurality, the filling composition 100 may include the first particles 104 respectively having substantially different diameters. Additionally, the first particle 104 may occupy about 5 volume % to about 40 volume % of the total volume of the filling composition.

The second particle 102 may be a solder ball including metal. According to some embodiments of the present invention, the second particle 102 may be at least one selected from the group consisting of Sn, Bi, In, Ag, Pb, and Cu. For example, the second particle 102 may be at least one selected from the group consisting of 60Sn/40Bi, 52In/48Sn, 97In/3Ag, 57Bi/42Sn/1Ag, 58Bi/42Sn, 52Bi/32Pb/16Sn, and 96.5Sn/3Ag/0.5Cu.

The diameter of the second particle 102 may range between about 5 nm and about 50 μm. For example, if the second particle is in plurality, the filling composition 100 may include the second particles 102 respectively having substantially different diameters. Moreover, the second particle 102 may occupy about 5 volume % to about 40 volume % of the total volume of the filling composition.

According to an embodiment of the present invention, the volume of both the first and second particles 104 and 102 may occupy about 30 volume % to about 50 volume % of the total volume of the filling composition.

The resin 110 may include a high molecular compound, a hardener, and a reducer.

The high molecular compound may include at least one monomer selected from the group consisting of diglycidyl ether of bisphenol A (DBEBA), tetraglycidyl 4,4′-diaminodiphenyl methane (TGDDM), tridiaminodiphenyl methane (triDDM), isocyanate, and bismaleimide.

The hardener may include amines and/or anhydrides. According to some embodiments of the present invention, the hardener may be at least one selected from the group consisting of m-phenylenediamine (MPDA), diaminodiphenyl methane (DDM), diaminodiphenyl sulphone (DDS), methylnadic anhydride (MNA), dodecenyl succinic anhydride (DDSA), maleic anhydride (MA), succinic anhydride (SA), methyl tetrahydrophthalic anhydride (MTHPA), hexahydrophthalic anhydride (HHPA), tetrahydrophthalic anhydride (THPA), and pyromellitic dianhydride (PMDA).

The hardener may be a range between about 0.4 equivalent and about 1.2 equivalent. That is, the equivalence ratio of the functional group of the hardener to a monomer constituting the resin 110 may range between about 0.4 and about 1.2.

According to some embodiments of the present invention, if the hardener includes an anhydride, the second particle 102 may serve as curing catalyst of the filling composition 100.

The reducer may serve to remove an oxide from the filling composition 100. Moreover, the weight of the reducer may change according to the reduction properties and reaction properties of the resin 110 of the second particle 102. According to embodiments of the present invention, the reducer added may be less than about 10 per hundred resin (phr) of the resin 110. The unit phr represents the weight of material added per 100 resin weight. For example, if the reducer is added in an amount of about 10 phr of the weight of the resin 110 and the resin 110 has a weight of about 100 g, the weight of the reducer is about 10 g.

The reducer may include a carboxyl (—COOH) material. According to embodiments of the present invention, the reducer may be at least one selected from the group consisting of glutaric acid, malic acid, azelaic acid, abietic acid, adipic acid, ascorbic acid, acrylic acid, and citric acid.

Since the reducer has a function for removing an oxide from the filling composition 100, when heat is applied to the filling composition 100, wet properties between the first and second particles 104 and 102 can be improved. Accordingly, due to the improved wetting properties in addition to the physical contacts made by conductive materials in the filling composition 100, the filling composition 100 can have excellent electrical conductivity.

According to some embodiments of the present invention, the filling composition 100 may further include a catalyst and a deforming agent.

The catalyst determines the time needed to harden the first and second particles 104 and 102 after applying heat to the filling composition 100 according to the weight of the catalyst. According to some embodiments of the present invention, the catalyst added may be less than about 30 phr of the weight of the resin 110.

The catalyst may be at least one selected from the group consisting of benzyl dimethyl amine (BDMA), boron trifluoride monoethylamine comples (BF3-MEA), dimethylamino methyl phenol (DMP), and dimethyl benzol amine (DMBA).

The deforming agent may be at least one selected from the group consisting of acrlylate oligomer, polyglycols, glycerides, polypropylene glycol, demethylsilicon, simethicone, tributyl phosphate, and polydimethylsiloxane.

(Method of Fabricating a Semiconductor Device)

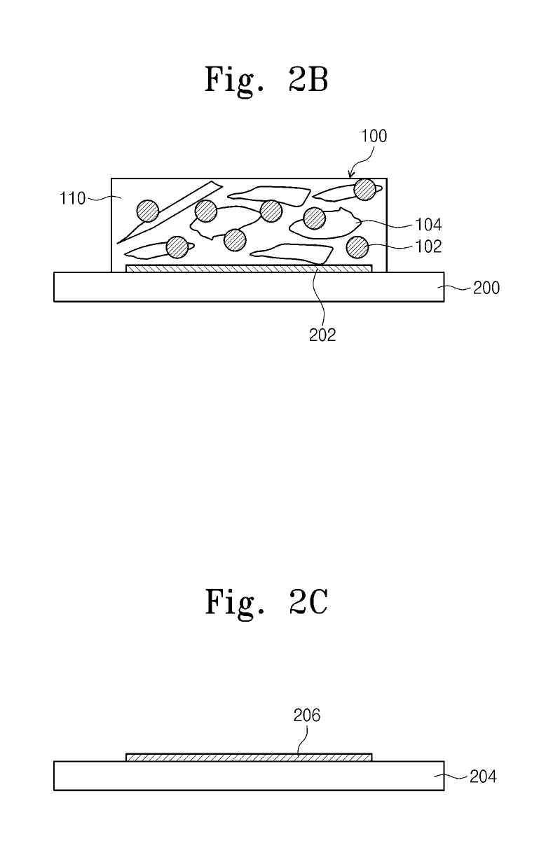

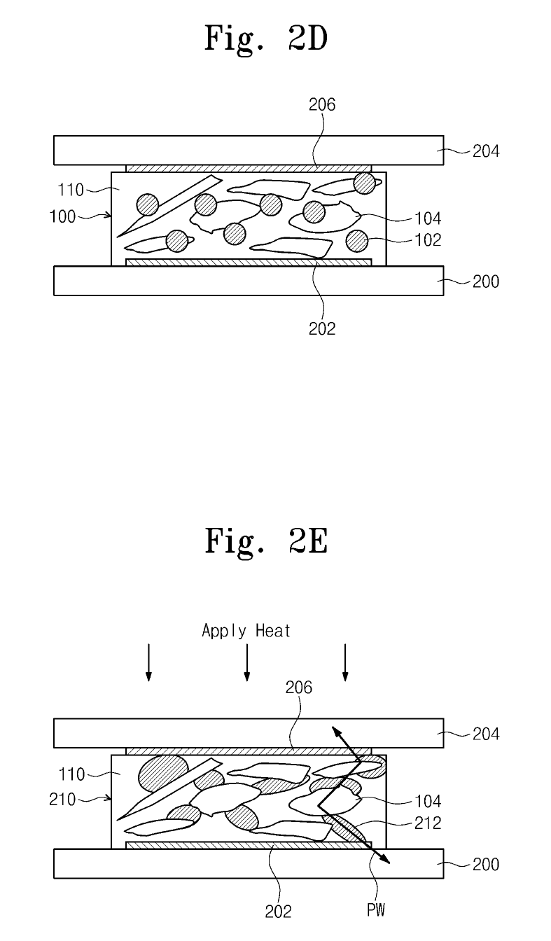

FIGS. 2A through 2E are sectional views illustrating a method of fabricating a semiconductor device according to an embodiment of the present invention. According to embodiments of the present invention, a semiconductor device may include a connection pattern formed of the filling composition shown in FIG. 1.

Referring to FIG. 2A, a first substrate 200 including a first conductive pattern 202 may be prepared.

The first substrate 200 may be a substrate including a semiconductor chip. The first conductive pattern 202 may be electrically connected to the semiconductor chip.

According to an embodiment of the present invention, the first conductive pattern 202 may be formed on the first substrate 200. In this case, the first conductive pattern 202 may have a structure protruding from the first substrate 200.

According to another embodiment of the present invention, the first conductive pattern 202 is formed in the first substrate 200, such that only the top surface of the first conductive pattern 202 may be exposed. In this case, the top surfaces of the first conductive pattern 202 and the first substrate 200 may be in the substantially same level.

Referring to FIG. 2B, a preliminary connection pattern 100, which is electrically connected to the first conductive pattern 202, may be formed. In more detail, one side of the preliminary connection pattern 100 may be formed to be in contact with the first conductive pattern 202 and the first substrate 200.

The preliminary connection pattern 100 may include the filling composition 100 of FIG. 1. In brief description, the filling composition 100 may include a particle 104 of copper and silver, solder power 102, a resin 110 formed of a high molecular compound, a hardener, and a reducer. The particle 104 including copper and silver and the solder power 102 of the filling composition 100 according to an embodiment of the present invention may correspond to the first particle and the second particle of FIG. 1, respectively.

Referring to FIG. 2C, a second substrate 204 including a second conductive pattern 206 may be prepared.

The second substrate 204 may be a circuit substrate. An example of the circuit substrate includes a printed circuit board (PCB) where a circuit pattern of a copper foil at one side of a core formed of reinforced glass fiber or epoxy resin. The circuit pattern may include a pattern for providing a path for electrical signals used for exchanging data with the first substrate 200, a pattern for delivering power to the first substrate 200 or ground, and a pattern for connecting to an external terminal. According to one embodiment, the second conductive pattern 206 may be formed on the second substrate 204. According to another embodiment of the present invention, the second conductive pattern 206 may be formed in the second substrate 204.

Referring to FIG. 2D, the second substrate 204 may be positioned to allow the second conductive pattern 206 to contact the preliminary connection pattern 100.

With this, the first conductive pattern 202 is disposed to contact one side of the preliminary connection pattern 100 and the second conductive pattern 206 may be disposed to contact the other side of the preliminary connection pattern 100.

Referring to FIG. 2E, by heating the preliminary connection pattern 100 of FIG. 2D, a connection pattern 210 that electrically connects the first and second conductive patterns 202 and 206 may be formed.

According to embodiments of the present invention, if the preliminary connection pattern 100 is heated, a solder ball 212 in the filling structure is melted and thus may electrically connect the particles 104 including copper or silver. For example, if the solder ball 212 includes 58Sn/42Bi, the melting temperature of the solder ball 212 may be about 150° C. Accordingly, when the preliminary connection pattern 100 is heated at a temperature of more than about 150° C., the solder ball 212 is melted and thus may electrically connect the particles 104 including copper or silver.

According to another embodiment, the connection pattern 210 may be formed by physically pressing the second substrate 204 and performing the above heating process simultaneously.

Furthermore, while the preliminary connection pattern 100 is heated, the reducer in the filling structure may remove an oxide in the preliminary connection pattern 100. Accordingly, wetting property between the particle 104 including copper or silver and the solder ball 212 can be improved such that the solder ball 212 may be electrically connected to the particle 104 including copper or silver more effectively. In addition, since an oxide in the connection pattern 210 is removed, thermal characteristics can be improved.

### Composition Example

A filling composition for an oxide removal function and curing reaction was manufactured by mixing epoxy based diglycidyl ether bisphenol A (DGEBA) and copper particles, 58Sn/42Bi, a hardener, a calayzer, and a reducer.

In more detail, an initial filing composition was formed by mixing 10 volume % of 58Sn/42Bi with 100 weight % of a resin including DGEBA, DDS having an equivalence ratio of 0.8 with respect to epoxy, 0.5 weight % of BF3MEA, and 20 weight % of malic acid. At this point, the diameter of 58Sn/42Bi was about 10 μm.

In Example 1, a composition was prepared by adding 20 volume % of copper particles to the initial filling composition. In Example 2, a composition was prepared by adding 25 volume % of copper particles to the initial filling composition. In Example 3, a composition was prepared by adding 27 volume % of copper particles to the initial filling composition. At this point, each copper particle had a diameter of about 3 μm.

In Comparative Example, a filling composition including silver particles of about 2 μm to about 10 μm and a resin was prepared. The silver piece occupied about 30 volume % of the filling composition and the resin occupied about 70 volume % of the filling composition.

Each of the filling compositions from Examples 1 to 3 and Comparative Example was inserted between a first substrate including a first conductive pattern and a second substrate including a second conductive pattern, which is then heated to about 160° C. under a heating condition of about 70° C./min. After 1 min., the electrical contact resistance was measured.

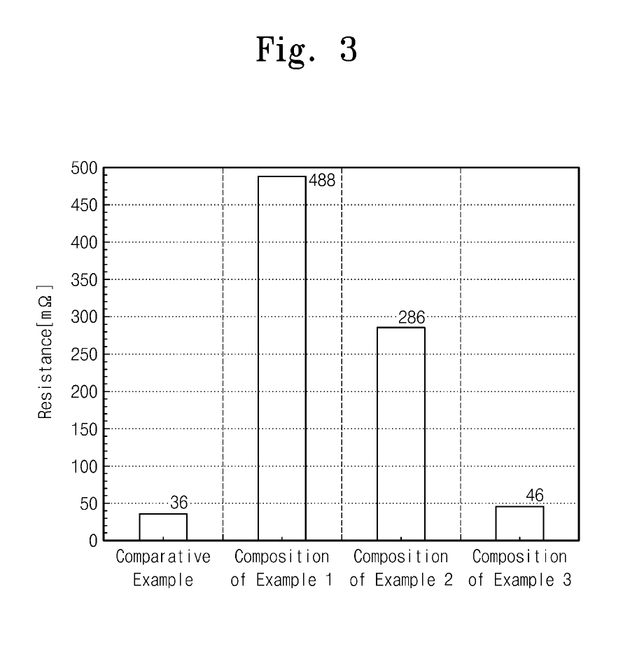

FIG. 3 is a graph illustrating the resistance values of the filling compositions of Examples 1 to 3 and Comparative Example, in which X-axis represents the filling compositions and Y-axis represents resistance values. The unit is in milliohm (mΩ).

Referring to FIG. 3, according to Comparative Example, the electrical resistance value of the filling composition including silver particles is less than those of the filling compositions of Examples 1 to 3.

Moreover, in Examples 1 to 3, as the content of copper particles in the filling composition is increased, the contact resistance value decreases. Specifically, the filling composition of Example 1 has a resistance value of about 488 nm, the filling composition of Example 2 has a resistance value of about 286 nm, and the filling composition of Example 3 has a resistance value of about 45 nm.

According to embodiments of the present invention, by applying a filling composition including copper instead of silver to semiconductor devices, cost efficiency can be improved. Additionally, by removing an oxide using a reducer in the filling composition, wetting property in first and second particles can be improved such that the thermal and electrical conduction characteristics of semiconductor devices can be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A filling composition comprising:
a first particle including Cu and/or Ag;
a second particle electrically connecting the first particles; and
a resin containing a high molecular compound, a hardener, and a reducer, in which the first and second particles are dispersed,
wherein the hardener includes amine and/or anhydride, and the reducer includes carboxyl.

2. The filling composition of claim 1, wherein:
the first particle occupies about 5 volume % to about 40 volume % of the composition; and
the second particle occupies about 5 volume % to about 40 volume % of the composition.

3. The filling composition of claim 1, wherein the first and second particles occupy about 30 volume % to about 50 volume % of the composition.

4. The filling composition of claim 1, wherein the second particle is at least one selected from the group consisting of Sn, Bi, In, Ag, Pb, and Cu.

5. The filling composition of claim 1, wherein the second particle is at least one selected from the group consisting of 60Sn/40Bi, 52In/48Sn, 97In/3Ag, 57Bi/42Sn/1Ag, 58Bi/42Sn, 52Bi/32Pb/16Sn, and 96.5Sn/3Ag/0.5Cu.

6. The filling composition of claim 1, wherein the high molecular compound includes at least one monomer selected from the group consisting of A (diglycidyl ether of bisphenol A, DBEBA), (tertraglycidyl4,4′-diaminodiphenyl methane, TGDDM), tridiaminodiphenyl methane, triDDM), isocyanate, and bismaleimide.

7. The filling composition of claim 1, wherein the hardener has an equivalent of an about 0.4 to about 1.2 of the high molecular compound.

8. The filling composition of claim 1, wherein the hardener is at least one selected from the group consisting of (m-phenylenediamine, MPDA), (diaminodiphenyl methane, DDM), (diaminodiphenyl sulphone, DDS), (methylnadic anhydride, MNA), (dodecenyl succinic anhydride, DDSA), (maleic anhydride, MA), (succinic anhydride, SA), (methyl tetrahydrophthalic anhydride, MTHPA), (hexahydrophthalic Anhydride, HHPA), (tetrahydrophthalic anhydride, THPA), and (pyromellitic dianhydride, PMDA).

9. The filling composition of claim 1, wherein the reducer is added in an amount of less than about 10 per hundred resin (phr) of the weight of the resin.

10. The filling composition of claim 1, wherein the reducer is at least one selected from the group consisting of glutaric acid, malic acid, azelaic acid, abietic acid, adipic acid, ascorbic acid, acrylic acid, and citric acid.

11. The filling composition of claim 1, wherein the diameter of the first particle is between about 1 μm and 30 μm and the diameter of the second particle is between about 5 nm and 100 μm.

12. The filling composition of claim 1, further comprising a catalyst and a deforming agent.

13. The filling composition of claim 12, wherein the catalyst is added in an amount of less than 30 per hundred resin (phr) of the weight of the resin.

14. The filling composition of claim 12, wherein the catalyst is at least one selected from the group consisting of (benzyl dimethyl amine, BDMA), boron trifluoride monoethylamine comples, BF3-MEA), (dimethylamino methyl phenol, DMP), and (dimethyl benzol amine, DMBA).

15. The filling composition of claim 12, wherein the deforming agent is at least one selected from the group consisting of acrlylate oligomer, polyglycols, glycerides, polypropylene glycol, demethylsilicon, simethicone, tributyl phosphate, and polydimethylsiloxane.

16. A semiconductor device comprising:
a first substrate formed with a first conductive pattern;
a second substrate formed with a second conductive pattern that is disposed to face the first conductive pattern; and
a connection pattern electrically connecting the first and second conductive patterns,
wherein the connection pattern includes a filling composition formed of a resin that contains a particle including Cu or Ag, solder powder, a high molecular compound, a hardener, and a reducer; the hardener includes amine and/or anhydride; and the reducer includes carboxyl.

17. The semiconductor device of claim 16, wherein the solder powder is at least one selected from the group consisting of Sn, Bi, In, Ag, Pb, and Cu and electrically connects the Cu particles.

18. The semiconductor device of claim 16, wherein:
the Cu particle occupies about 5 volume % to about 40 volume % of the filling composition; and
the solder power occupies about 5 volume % to about 40 volume % of the filling composition.

19. A method of fabricating a semiconductor device, the method comprising:
preparing a first substrate formed with a conductive pattern;
forming a preliminary connection pattern on the first substrate;
preparing a second substrate formed with a second conductive pattern;
positioning the second substrate to allow the second conductive pattern to contact the preliminary connection pattern; and
forming a connection pattern that electrically connects the first and second conductive patterns by applying heat to the preliminary connection pattern,
wherein the preliminary connection pattern includes a filling composition formed of a resin that contains a particle including Cu or Ag, solder powder, a high molecular compound, a hardener, and a reducer; the hardener includes amine and/or anhydride; and the reducer includes carboxyl.

20. The method of claim 19, wherein the forming of a connection pattern comprises:
removing an oxide in the preliminary connection pattern through the reducer by applying heat to the preliminary connection pattern; and
electrically connecting the Cu particles by expansion of a ball of the solder powder.
